(19) United States
(12) Patent Application Publication
(10) Pub. No.: US 2012/0318350 A1
(43) Pub. Date: Dec. 20, 2012

(54) DOPANT MATERIAL, SEMICONDUCTOR SUBSTRATE, SOLAR CELL ELEMENT, AND PROCESS FOR PRODUCTION OF DOPANT MATERIAL

(75) Inventors: Youhei Sakai, Yasu-shi (JP); Satoshi Kawamura, Higashiomi-shi (JP); Mayu Takimoto, Omihachiman-shi (JP)

(73) Assignee: KYOCERA CORPORATION, Kyoto-shi, Kyoto (JP)

(21) Appl. No.: 13/580,664

(22) PCT Filed: Feb. 23, 2011
(86) PCT No.: PCT/JP2011/053991

§ 371 Date: Aug. 22, 2012

(30) Foreign Application Priority Data
Feb. 23, 2010 (JP) 2010-036839

(51) Int. Cl. H01L 29/16; H01L 21/22; H01L 31/0224

(52) U.S. Cl. 136/256; 257/49; 438/557; 257/E29.082; 257/E21.14

(57) ABSTRACT

A dopant material is disclosed. The dopant material comprises a polycrystalline silicon and a dopant element in the polycrystalline silicon. A concentration of the dopant element is at least 1×10¹⁸ atoms/cm³ and no greater than 1×10²⁰ atoms/cm³. A method for producing a dopant material is also disclosed. A fused mixture is generated by mixing and fusing a silicon material with an element that serves as the dopant source. A coagulate of the dopant material is generated by cooling and coagulating the fused mixture. A semiconductor substrate is disclosed. The semiconductor substrate comprises a semiconductor material to which the dopant material is added. A solar cell element comprising the semiconductor substrate, a first electrode, and a second electrode is disclosed. The semiconductor substrate comprises a first surface and a second surface corresponding to a rear surface of the first surface.

### FIELD OF ART

The present invention relates to a dopant material used for making a silicon ingot.

### BACKGROUND ART

Conventionally, a silicon substrate has been used as a type of semiconductor substrate for forming a solar cell element. Such a silicon substrate is obtained by processing a single-crystal silicon ingot or polycrystalline silicon ingot produced by the CZ method or casting method or the like to a prescribed size.

In order to have the desired electrical characteristics, the silicon substrate comprises a prescribed amount of a dopant. When fabricating a p-type semiconductor, boron is generally used as the element that serves as the dopant source. The following method is used to produce silicon (a silicon ingot) that comprises dopant of a prescribed concentration.

First, a dopant material made of boron alone or of single-crystal silicon comprising a large amount of boron is introduced into the silicon material that will serve as the raw material, and melting by heat is done to produce a fused mixture. Then, a prescribed method is used to cause coagulation and cooling of the fused mixture. By doing this, silicon (a silicon ingot) comprising the prescribed concentration of dopant is produced.

For example, Japanese Laid-open Patent Publication No. 2006-273668 discloses a silicon substrate for use into a solar cell element, in which a prescribed amount of a dopant material is introduced, so that the resistivity is 0.1 Ω·cm to 10 Ω·cm.

If boron alone is used as the dopant material, in the case of fabricating a silicon substrate having a large resistivity such as is used in a solar cell element, an introduced amount of dopant material becomes very small, and there are cases in which control thereof is difficult.

Given this, by using a dopant material made of single-crystal silicon that comprises a large amount of boron, it is possible to make the introduced amount of dopant material introduced large, thereby facilitating control of the dopant material and, by extension, the dopant concentration. This type of dopant material is usually used by crushing a single-crystal silicon ingot comprising a large amount of the dopant source. However, because single-crystal silicon is extremely hard, it is difficult to crush.

### SUMMARY OF THE INVENTION

One object of the present invention is to provide a dopant material having high productivity, a silicon substrate manufactured using the dopant material, solar cell element, and a method for producing the dopant material.

A dopant material according to one embodiment of the present invention is a dopant material that is to be added to a silicon-containing semiconductor material, and that comprises an element that serves as an n-type or a p-type dopant source and polycrystalline silicon. The concentration of the element serving as the dopant source is at least 1×10¹⁸ atoms/cm³ and no greater than 1×10²⁰ atoms/cm³.

A semiconductor substrate according to an embodiment of the present invention comprises a semiconductor material to which the above-noted dopant material is added.

A solar cell element according to an embodiment of the present invention comprises the above-noted semiconductor substrate; a first electrode that is positioned on either a first surface or a second surface semiconductor substrate, and a second electrode that is positioned on the second surface of the semiconductor substrate.

A method for producing a dopant material according to an embodiment of the present invention comprises a step of mixing and fusing a silicon material with an element that serves as the dopant source, so as to generate a fused mixture, and a step of cooling the fused mixture, so as to generate a coagulate of the dopant material that comprises the element that serves as the dopant source and polycrystalline silicon.

In the dopant material of this embodiment, by causing polycrystalline silicon to comprise the element that serves as the dopant source with a concentration of at least 1×10¹⁸ atoms/cm³ and no greater than 1×10²⁰ atoms/cm³, compared to a dopant material made of single-crystal silicon, there are more crystal grain boundaries and crystal defects. For this reason, it is easy to crush, and it is possible to reduce the amount of time required to crush the dopant material finely, thereby facilitating the preparation of the prescribed amount of dopant material, and improving productivity.

In the method for producing a dopant material according to this embodiment, by adopting the constitution described above, it is possible to efficiently produce a dopant material in which the element serving as the dopant source is comprised in polycrystalline silicon.

### BRIEF DESCRIPTION OF THE DRAWINGS

FIG. 1 is a schematic cross-sectional view showing an apparatus for producing a dopant material (polycrystalline silicon ingot) according to an embodiment of the present invention.

FIG. 2 is a descriptive drawing showing an example of the separation into blocks of coagulates that are obtained as intermediate products in the process of producing a dopant material according to an embodiment of the present invention.

FIG. 3 is a cross-sectional view showing a solar cell element according to an embodiment of the present invention.

FIG. 4 is a cross-sectional view showing a solar cell element according to another embodiment of the present invention.

### EMBODIMENTS FOR PRACTICING THE INVENTION

A dopant material, a semiconductor substrate, a solar cell element, and a method for producing the dopant material according to embodiments of the present invention will be described below, using drawings.

### <Dopant Material>

In a dopant material according to an embodiment of the present invention, an element that serves as a dopant source is comprised in polycrystalline silicon. The purity of the polycrystalline silicon used can be the same purity as the silicon material used when producing a silicon ingot for a solar cell, for example, 99.9999% or greater.

In this case, the concentration of the element in the dopant material is at least 1×10¹⁸ atoms/cm³ and no greater than 1×10²⁰ atoms/cm³.

The element that serves as the dopant source may be, for example, in the condition that all of the element that serve as the dopant source are dissolved in the polycrystalline silicon. Alternatively, in the case in which the element that serves as the dopant source is saturated in the dopant material, a part of the element that serves as the dopant source may be in the condition of being precipitated out at the crystal grain boundaries in the polycrystalline silicon.

By virtue of this constitution, the dopant material of the present embodiment has a large number of crystal grain boundaries and crystal defects. For this reason, it is easy to crush, and it is possible to reduce the amount of time required to crush it finely, thereby facilitating the preparation of a prescribed amount of dopant material, and improving the productivity.

In this case, the element that is used as the dopant source is an element that exhibits p-type or n-type characteristics from Group III or Group V, such as P, B, Ga, Sb, As or the like.

The dopant material according to the present embodiment is a p-type dopant material and comprises boron as the element serving as the dopant source. The concentration of the boron is at least 1×10¹⁸ atoms/cm³ and no greater than 1×10²⁰ atoms/cm³. Such a dopant material that comprises boron is suitable for use in the manufacturing of diverse semiconductor substrates, such as for a solar cell element.

The resistivity of a dopant material comprising this concentration of boron is, for example, at least approximately 1.2 mΩ·cm and no greater than 60 mΩ·cm. By making the resistivity of the dopant material fall within that range, when manufacturing a silicon ingot for a solar cell, it is possible to produce the silicon ingot with the prescribed resistivity with good control. Here, the concentration of the boron (Cb) can be approximately calculated by the following equation.

Cb=1/(ρb×q×μ)

In the above, ρb is the resistivity (in units of Ω·cm), q is the elementary electric charge (1.6×10¹⁹ (in units of C)), and μ is the hole mobility (in units of cm2/(V·s)). Also, a prescribed value may be used for the mobility μ or, because of the dependency on the dopant concentration, a value obtained from a conversion table (Irvin curves) based on ASTM F723-81 may be used for the mobility μ.

Also, the boron concentration may be made at least 5×10¹⁸ atoms/cm³ and no greater than 8×10¹⁹ atoms/cm³. By making the boron concentration fall within this range, it is possible, while reducing the variation in the resistivity value, to reduce the mass of dopant material introduced when producing a silicon ingot for use in a solar cell. By doing this, in addition to improving the cost advantage, it is possible to achieve good control of the dopant concentration.

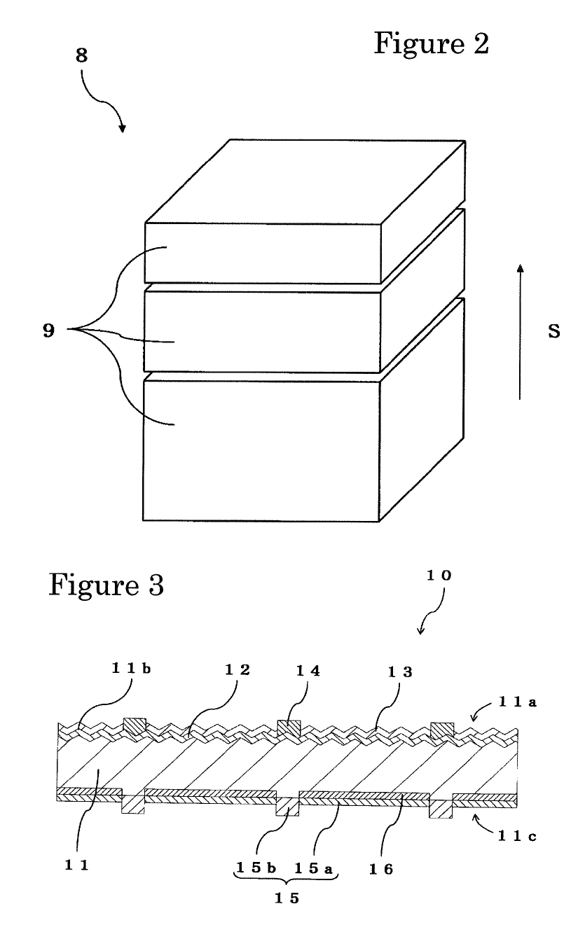

The value of resistivity as referred to herein, for example, as shown in FIG. 2 described later, can be taken as the average value of a first resistivity value that is measured at a first surface positioned upstream in a first direction and a second resistivity value that is measured at a second surface positioned downstream in the first direction in the dopant material, which is a block. From this average value, it is possible to calculate the boron concentration comprised in the dopant material, using the approximate calculation method described above. The first surface and second surface as referred to herein can be taken as the upstream and downstream cross-sections described later that occur by slicing (cutting of the coagulate) to form each of the blocks.

In the present embodiment, oxygen is further comprised as an impurity. The concentration of the oxygen may be at least 3×10¹⁵ atoms/cm³ and no greater than 1×10¹⁸ atoms/cm³ as measured by SIMS (secondary ionization mass spectrometry). The oxygen concentration may be at least 1×10¹⁶ atoms/cm³ and no greater than 1×10¹⁸ atoms/cm³ and further may be at least 1×10¹⁶ atoms/cm³ and no greater than 4×10¹⁷ atoms/cm³.

For example, in the case of using the CZ method to produce a dopant material in which single-crystal silicon is caused to contain boron as the dopant source, a quartz crucible into which few impurities are mixed during melting is used and it is pulled upward from the silicon melt within the quartz crucible. For this reason, the silicon melt captures oxygen component comprised in the quartz, so that it comprises a large amount of oxygen. When this occurs, a resistivity value that is higher than that indicated by the actual boron concentration tends to be measured when the oxygen concentration is high, because the oxygen behaves as a thermal donor. In the present embodiment, however, the oxygen concentration is in the above-noted range. It is thus possible to improve the accuracy of the boron concentration calculated from the value of resistivity of the dopant material.

The SIMS measurement is the method in which an accelerated and narrowly constricted primary ion beam (oxygen, cesium, or the like) is caused to strike a sample in a vacuum and, of the particles that fly off the sample surface by sputtering, secondary ions are extracted by an electric field and subjected to mass analysis. Then, a comparison is done with a standard sample to convert to an absolute concentration, thereby enabling measurement of the oxygen concentration. For example, the following measurement conditions can be used to measure the oxygen concentration.
Apparatus used: Cameca IMS-4f
Primary ion type: Cs+
Primary ion accelerating voltage: 14.5 kV
Raster region: 125 μm
Analysis region: 30 μm diameter
Measurement vacuum: 1×10⁻⁷ Pa

The measurement conditions are not restricted to these conditions.

In this present embodiment, the dopant material may have a first region positioned upstream in a first direction and a second region positioned downstream with respect to the first region. In this case, the boron concentration in the first region is greater than the boron concentration in the second region. Additionally, the oxygen concentration in the first region is smaller than the oxygen concentration in the second region. By virtue of such a constitution, by making the oxygen concentration low in a region in which the dopant concentration is high, it is possible to reduce the reduction in the measurement accuracy of the resistivity value. As a result, there is an improvement in the productivity. Also, in particular if the dopant concentration in the dopant material is high, because the mass of the dopant material used when producing the silicon ingot is reduced, the error in the resistivity value has a great influence on the resistivity value of the silicon ingot, which is the ultimate product. In contrast, with a dopant material having the above-noted constitution, it is possible to easily obtain the desired value of resistivity.

Additionally, in the present embodiment, the oxygen concentration may be made to decrease in a gradual or step-like manner moving from the second region toward the first region along the first direction. By virtue of such a constitution, along with the gradually increasing dopant concentration moving toward the first region, the oxygen concentration is, in reverse, reduced in a gradual or step-like manner going. By doing this, it is possible to reduce the reduction in the accuracy of measuring the resistivity value. Also, because there is no necessity for special processing to reduce the oxygen concentration in the second region, the result is that there is a further improvement in the productivity.

Further, the reduction rate of the oxygen concentration in the first region may be smaller than the reduction rate of the oxygen concentration in the second region. By virtue of such a constitution, by making the reduction rate in the first region small, that is, by making the reduction rate in the second region large, it is possible to make the oxygen concentration in the overall first region low. By doing this, it is possible to further reduce the reduction in the accuracy of measuring the resistivity value. As a result, there is a further improvement in the productivity.

In the present embodiment, the first region and the second region may be regions that satisfy the above-described positional relationship in the first direction and also satisfy the above-described magnitude relationship between the concentrations of elements.

Also, in the present embodiment, the concentration of each element in the first region can be made, for example, the concentration of each element measured at the end face of a block that is positioned upstream in the first direction and also perpendicular to the first direction. In the same manner, the concentration of each element in the second region can be made, for example, the concentration of each element measured at the end face of a block that is positioned downstream in the first direction and also perpendicular to the first direction.

Additionally, the reduction rate of the oxygen concentration can be established, for example, as follows, if in the first region. Specifically, if the oxygen concentration on the upstream side in the first direction in the first region is C1 and the oxygen concentration on the downstream side in the first direction is C2, the reduction rate of the oxygen concentration is expressed as (C2−C1)/C2×100%.

Also, in the present embodiment, although the method of measuring the concentration of the dopant element has been described by the example of the dopant material in the form of a block, the shape of the dopant material is not particularly restricted to this. For example, it may be, for example, spherical. That is, as long as the “dopant material” as used herein comprises an element that will serve as the dopant source with the above-described high concentration, and can be added to a semiconductor material, it may be any shape. Also, from the standpoint of ease of working, the dopant material can be made into the form of a block or a plate-like body.

### <Method for Producing a Dopant Material>

Next, an embodiment of a method for producing a dopant material according to the present invention will be described. First, the manufacturing apparatus used when producing the dopant material according to the present embodiment will be described.

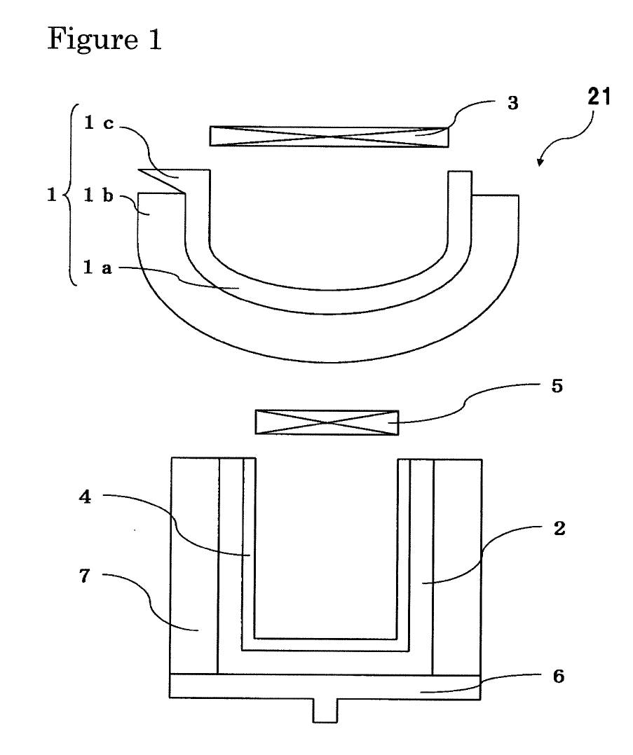

The apparatus 21 that produces the dopant material, as shown in FIG. 1, has a crucible 1, a mold 2, a crucible heating means 3, mold-releasing material 4, a mold-heating means 5, a cooling means 6, and thermal insulation material 7. A manufacturing apparatus for a polycrystalline silicon ingot manufactured by casting method can be used as the manufacturing apparatus 21.

The crucible 1 comprises a melting part 1a, a holding part 1b, and a pouring spout 1c. The melting part 1a has an aperture that opens upwardly. The melting part 1a holds within it the silicon material and the element that will serve as the dopant source that have been place therein. The materials that have been placed therein are melted by heating, a silicon melt, which is a fused mixture, being formed. The silicon melt is then poured into the mold 2. Quartz of high purity or the like can be used as the material for the melting part 1a. The holding part 1b holds the melting part 1a, and is made of, for example, graphite. The pour spout 1c functions to pour the silicon melt, and is formed at an upper edge of the melting part 1a. The silicon melt is poured from the pouring spout 1c into the mold 2. The shapes of the melting part 1a and the holding part 1b are not restricted to those shown in FIG. 1.

The crucible heating means 3 is disposed at the top part of the melting part 1a. A resistance-type heater or induction heating coil or the like can be used as the crucible heating means 3.

The mold 2 has an aperture that opens upwardly. The mold 2 receives the silicon melt formed within the crucible 1 from this aperture. The mold 2 functions to hold the silicon melt therewithin while causing coagulation thereof in one direction, from bottom to top. The mold 2 is made of, for example, a carbon material such as graphite, or of quartz or fused silica.

The mold releasing material 4 is coated on the inside surface part of the mold 2. The mold releasing material 4 may be formed by coating the mold 2 with a slurry which is obtained by mixing and agitating silicon nitride into a solution constituted by an organic binder and a solvent. When this is done, polyvinyl alcohol, polyvinyl butyral, or methylcellulose or the like can be used as the organic binder.

The mold heating means 5 is disposed over the mold 2, and can be a resistive-type heater or induction heating coil or the like. The mold heating means 5, by heating the silicon melt poured into the mold 2 to an appropriate degree, heats the surface of the silicon melt to an appropriate degree. By doing this, it is possible to more accurately control the temperature gradient from the bottom to the top in the silicon melt within the mold 2.

The cooling means 6 is disposed below the mold 2 and functions to cause the poured silicon to cool and to coagulate by removing heat from the bottom thereof. The cooling means 6 is, for example, made from a metal plate. Specifically, a cooling means with a structure in which water or a gas is caused to circulate within hollow metal plates or the like can be used. By the cooling means 6 approaching the bottom part of the mold 2 in a non-contacting condition, or coming into contact therewith, the silicon melt can be cooled from beneath.

The thermal insulation material 7 is disposed at the periphery of the mold 2 and functions to suppress the removal of heat from the sides of the mold. Considering heat resistance and heat insulation, for example, carbon felt or the like can be used as the material of the heat insulation material 7.

The manufacturing apparatus 21 can be disposed within a vacuum vessel (not shown) and be used under the condition of a reduction atmosphere such as an inert gas, in which case it is possible to reduce the intrusion of impurities and oxidation of materials during the manufacturing process.

A method for producing a dopant material that uses the above-described manufacturing apparatus 21 will be described.

First, the fused mixture is produced. Specifically, a prescribed amount of silicon material within the crucible 1 is mixed with an element that will serve as the dopant source. When this is done, for example, the silicon material is held at the bottom of the melting part 1a, the dopant source is held thereover, and silicon material is further held thereover. The dopant source is held in the region of 15% to 85% of the overall height of the melting part 1a in the height direction of the melting part 1a. While the problem of the effect of the inert gas causing the dopant source to fly up so that the prescribed amount of dopant source is not dissolved in the silicon melt is reduced, doing this facilitates the dissolution of the dopant source into the silicon melt. Then, the crucible heating means 3 melts the silicon material and the boron, so as to form a fused mixture, that is, a silicon melt that comprises boron. In the present embodiment, boron is used as the element that serves as the dopant source. The quantities of the silicon material and the boron can be, for example, approximately 5 to 20 g of boron with respect to 100 kg of silicon material. In this case, it is possible to use a silicon material or the like that is used when producing a silicon ingot for a solar cell element, which is polycrystalline silicon.

Next, the fused mixture that is adjusted to a prescribed temperature is poured into the pre-heated mold 2. When this is done, for example, the crucible 1 and the mold 2 can be moved to a prescribed region, and the fused mixture can be poured from the crucible 1 into the mold 2.

Next, the fused mixture is cooled, so as to produce a coagulate 8. Specifically, as the mold heating means 5 heats the fused mixture from above, the cooling means 6 cools it from below. By doing this, a positive temperature gradient is established from the bottom part of the mold 2 up to the top part, and the fused mixture is cooled to form a coagulate successively from the bottom part upward toward the top part. By being subjected to this type of cooling process, a coagulate 8 that comprises polycrystalline silicon is produced. After that, several millimeters are removed from the edge surfaces of the bottom, top, and side parts of the coagulate 8, which have a high concentration of impurities such as iron.

Because boron has a segregation coefficient of 0.8 in silicon, it becomes concentrated in the silicon melt as the coagulation progresses. Because of this, the concentration of boron increases from the bottom part of the coagulate 8 toward the top part thereof. That is, the resistivity of the coagulate 8 decreases from the bottom part toward the top part. For this reason, a plurality of blocks 9 are formed by cutting the coagulate 8 along a direction that is perpendicular to one direction (the coagulation direction S), as shown in FIG. 2. The cutting positions can be appropriately selected so that the difference in resistivity between the bottom part and the top part of a block 9 is approximately 1 to 3 mΩ·cm. Although, for example, in the present embodiment the cutting is done into three blocks, cutting may be done so as to form three or more blocks.

As described above, in the coagulate 8, a distribution of resistivity occurs in one direction (the coagulation direction S), and the declining gradient of resistivity value tends to be larger at the top part than at the bottom part. For this reason, as shown in FIG. 2, the heights (lengths in the coagulation direction S) of the blocks 9 that are formed can be made so that a block 9 extracted from the bottom part is larger than a block 9 extracted from the top part. Specifically, the cutting positions can be determined as the result of calculating the boron concentration (resistivity) in the coagulation direction S, based on the mass and the segregation coefficient of the mixed boron. The method used for calculating the boron concentration (resistivity) can be the above-described method or the like.

The above-noted first direction corresponds to the coagulation direction S in this case, the above-noted upstream side in the first direction corresponds to the top part in the coagulation direction S in this case, and the above-noted downstream side in the first direction corresponds to the bottom part in the coagulation direction S in this case.

According to the method of the present embodiment, the blocks 9 having a plurality of steps of boron concentration are formed. The obtained blocks 9 can be used as dopant material. Specifically, when fabricating a silicon ingot, the block 9 can be sliced or crushed to adjust to the amount of dopant material to be introduced in accordance with the desired boron concentration.

In order to obtain the desired semiconductor substrate, the dopant material is required to have a level of quality that enables highly precise control of the concentration of the dopant source element. Given this, the resistivity at 10 to 40 points each on the top part and bottom part of the obtained block 9 may be, for example, measured, and the average value thereof can be taken as the resistivity value of the block 9, so as to control the concentration of the dopant element in the block 9 to be used as the dopant material. In this resistivity measurement as well, it is possible to use the various above-described measurement methods. For example, in the case of using the non-contact eddy current decay method, it is possible to increase the accuracy of quality control of the dopant material because it is possible to reduce the problem of variation of the resistivity value caused by the influence of crystal grain boundaries,.

As described above, the block 9, in which the concentration of the element serving as the dopant source is controlled based on resistivity measurements in this manner, is crushed, and the rubble, sand, particles, or powder, which is obtained by pulverizing, is used as the dopant material of the prescribed amount. Dopant material produced by an embodiment such as this comprises polycrystalline silicon as a main component. That being the case, it is easy to crush, enabling efficient crushing into small pieces because the dopant material produced by the present embodiment comprises a larger amount of crystal grain boundaries and crystal defects compared with a dopant material that comprises single-crystal silicon. As a result, it is easy to prepare the prescribed amount of dopant material, enabling an improvement in productivity.

According to the present embodiment, unidirectional coagulation in the obtained dopant material makes the resistivity value substantially same in a direction that is perpendicular to one direction (the coagulation direction S, that is, the first direction). For this reason, by making the size of the coagulate be, for example, 300 mm square or larger, it is possible to obtain a large amount of dopant material having a stable resistivity value, thereby enabling a reduction of the cost of producing the dopant material. By using, for example, casting method as the unidirectional coagulation method, it is easy to obtain a dopant material that has a large dimension in the lateral direction, that is, the direction that is perpendicular to the coagulation direction S. Also, for example, by cutting the coagulate 8 into squares of 10 to 15 cm along a direction parallel to the coagulation direction S, it is possible to make the difference in resistivity over the surface small and also possible to facilitate use as a dopant material and to improve the productivity thereof.

In the manufacturing method of the present embodiment, crystal seeds occur randomly at locations that are both the most cooled locations at the bottom part and locations in contact with the silicon melt, and multiple crystals proceed to grow from these points as origins. For this reason, the obtained dopant is generated as polycrystalline silicon in which the orientations of the individual crystals differ.

If the mold-releasing material 4 comprises silicon nitride, not only is mold removal easy, but also it is possible to reduce the intrusion of oxygen into the silicon melt even when using a mold 1 that has a silicon oxide component. In this case, in order to improve the strength of the mold-releasing material 4, a mixture of silicon nitride and a silicon oxide may be used as the mold-releasing material 4. If this is done, by making the ratio of silicon nitride to silicon oxide be 10:0 to 6:4, the increased amount of silicon oxide enables a reduction in the amount of oxygen that intrudes into the silicon melt within the mold 1.

The oxygen concentration in the coagulate 8 decreases from the bottom part of the coagulate 8 toward the top part thereof. That is, the oxygen concentration in the coagulate 8 decrease from the downstream side toward the upstream side along the coagulation direction S (first direction). This is because of release of silicon oxide (SiO2) gas from the silicon melt during the cooling step, which reduces the amount of oxygen that intrudes into the silicon melt due to the mold-releasing material 4. When this occurs, the oxygen concentration in the coagulate 8 decreases exponentially as the coagulation progresses. For this reason, it is possible to make the oxygen concentration at least 1×10¹⁶ atoms/cm³ and no greater than 4×10¹⁷ atoms/cm³ as measured by SIMS. By making the oxygen concentration fall within this range, it is possible to improve the accuracy of calculating the boron concentration from the value of resistivity.

It is therefore possible to reduce variation in resistivity over the surface, which is caused by a non-uniform oxygen concentration distribution, that is, the thermal donor distribution over the surface, which is viewed in the form of a dopant material that includes a single-crystal silicon ingot, when the polycrystalline silicon comprising dopant material is obtained from the above-described manufacturing method. That is, in the coagulate 8 produced by the above-described manufacturing method, because the oxygen concentration is low and it is possible to perform control so as to achieve uniformity of the resistivity value over the surface by unidirectional coagulation, it is possible to manufacture a uniform dopant material. The expression over the surface as used herein means over a surface that is perpendicular to the coagulation direction S.

In the manufacturing method according to the present embodiment, although the description has been for the case of pouring the silicon melt produced by melting the silicon material in the crucible 1 into the mold 2, the silicon material may be melted within the mold 2.

### <Semiconductor Substrate>

Next, a semiconductor substrate according to the present embodiment will be described.

The semiconductor substrate according to the present embodiment is obtained by manufacturing a semiconductor ingot, that is, a silicon ingot in which a dopant material produced as described above is added to a semiconductor material. More specifically, the semiconductor substrate for use in a solar cell element and that is obtained by the above-described dopant material will be described in detail for the present embodiment. In the present embodiment, silicon is used as the semiconductor material to which the dopant material is added.

A polycrystalline silicon ingot for use in a solar cell element can be manufactured by a variety of known silicon ingot manufacturing apparatuses. Manufacturing is possible using, for example, the polycrystalline silicon ingot manufacturing apparatus having the constitution shown by the schematic cross-sectional view of FIG. 1. The dopant material produced by the above-described manufacturing method and the silicon material are placed into the crucible 1 and heated to melting, and the silicon melt that is formed is poured into the mold 2, the inside surface of which is covered by the mold-releasing material 4. Then, the silicon melt is heated from above by the mold heating means 5 and cooled from the bottom part by the cooling means 6, so as to cause gradual unidirectional coagulation from the bottom part side of the mold 2. By the silicon melt completely coagulating, a polycrystalline silicon ingot is obtained. When this is done, the amount of dopant material introduced can be appropriately adjusted in accordance with the resistivity value of the dopant material, so that the polycrystalline silicon ingot has the desired resistivity. For example, 50 to 300 g of dopant material having a resistivity value of at least 1.2 mΩ·cm and no greater than 60 mΩ·cm may be introduced with respect to 100 kg of silicon material. Alternatively, the dopant material and silicon material may be introduced into the mold 2, not the crucible 1, and melted.

The silicon substrate (semiconductor substrate) for used in a solar cell element is obtained by removing the polycrystalline silicon ingot obtained as noted above from the mold 2, cutting it to a prescribed size, and then slicing it using a multi-wire saw or the like.

### <Solar Cell Element>

Next, a solar cell element 10 according to the first embodiment of the present invention that uses the above-described semiconductor substrate will be described.

The solar cell element 10 according to the present embodiment comprises a semiconductor substrate 11, a diffusion layer 12, an anti-reflection film 13, a first electrode 14, and a second electrode 15. It preferably further comprises a BSF (back surface field) layer 16.

As shown in FIG. 3, in the semiconductor substrate 11, a first surface (light-receiving surface) 11a side has a concavo-convex shape 11b.

The diffusion layer 12 is formed by diffusing an n-type impurity to a prescribed depth from the outside surface of the first surface 11a that has the concavo-convex shape 11b in the semiconductor substrate 11. By doing this, a p-n junction is formed between the semiconductor substrate 11 and the diffusion layer 12.

The anti-reflection film 13 is formed over the surface of the diffusion layer 12 and is made of, for example, silicon oxide, silicon nitride, or titanium oxide or the like.

The first electrode 14 and the second electrode 15 are formed by coating each first surface 11a and second surface 11c that corresponds to the rear surface of the first surface 11a of the semiconductor substrate 11 with a prescribed pattern of an electrode paste having silver as a main component and then firing. By the fire-through method, for example, the first electrode 14 can easily contact the diffusion layer 12. Alternatively, the second electrode 15 may have an aluminum electrode 15a and a silver electrode 15b, which are formed by coating the second surface 11c of the semiconductor substrate 11 with, for example, prescribed patterns of electrode pastes having aluminum as a main component and having silver as a main component respectively, and then firing.

The solar cell element 10 may further have a BSF layer 16. The BSF layer 16 is a high-concentration p-type diffusion layer that is provided on the second surface 11 c side of the semiconductor substrate 11. In the case in which the BSF layer 16 is formed using aluminum, it is formed by the diffusion of the aluminum into the semiconductor substrate 11 in the step of coating and firing an aluminum paste.

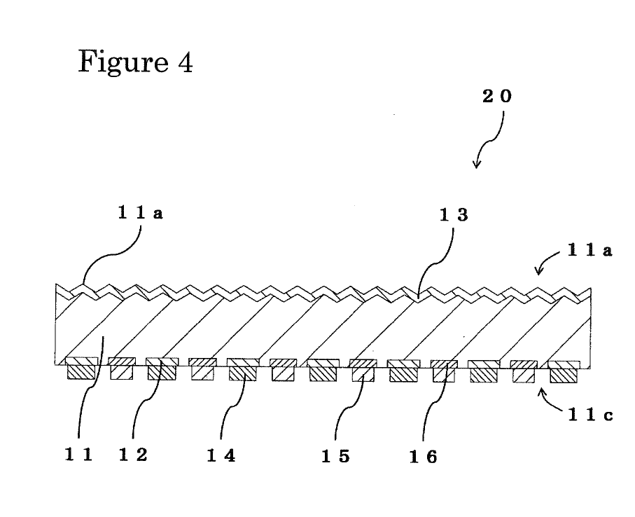

Next, a solar cell element 20 according to the second embodiment of the present invention will be described. As shown in FIG. 4, the solar cell element 20 of the present embodiment differs from the solar cell element 10 according to the first embodiment with regard to the provision therein of both the first electrode 14 and the second electrode 15 on the second surface 11c side (rear side) of the semiconductor substrate 11.

Specifically, in the present embodiment, an n-type diffusion layer 12 is formed on a part of the second surface 11c, the first electrode 14 is formed on the n-type region (diffusion region 12) on the second surface 11c, and the second electrode 15 is formed on the p-type region (BSF layer 16) on the second surface 11c. In this manner, the first electrode 14 and the second electrode 15, which output to the outside mutually different electrical charges, are provided on the second surface 11c of the semiconductor substrate 11. When this is done, for example, both the first electrode 14 and the second electrode 15 may be comb-tooth shaped and also provided so that there is a space therebetween.

While the foregoing has been a description of various embodiments of the present invention, the present invention is not restricted to the above-noted embodiments, and can be subjected to many modifications and changes within the scope of the present invention. That is, the present invention encompasses, of course, various combinations of the above-noted embodiments.

For example, the silicon material used to produce the dopant material may be the bottom part material or end part material of a silicon ingot for a solar cell element manufactured by casting method that cannot be used as a silicon substrate. If this is done, the bottom part material or end part material is material that is obtained by blasting or grinding to remove approximately 0.4 to 5 mm of the layer of the surface that had made contact with the mold-releasing material. By doing this, metal impurities and the mold-releasing material are removed, enabling re-use as silicon material.

### DESCRIPTION OF THE REFERENCE SYMBOLS

1 Crucible
1a Melting part
1b Holding part
1c Pouring spout
2 Mold
3 Crucible heating means
4 Mold-releasing material
5 Mold heating means
6 Cooling means
7 Thermal insulation material
10, 20 Solar cell element
11 Semiconductor substrate
11a First surface
11b concavo-convex surface
11c Second surface
12 Diffusion layer
13 Anti-reflection film
14 First electrode
15 Second electrode
16 BSF layer
21 Dopant material manufacturing apparatus

1. A dopant material, comprising:
a polycrystalline silicon; and
a dopant element comprised in the polycrystalline silicon,
wherein a concentration of the dopant element is at least 1×10¹⁸ atoms/cm³ and no greater than 1×10²⁰ atoms/cm³.

2. The dopant material according to claim 1, wherein the dopant element is boron.

3. The dopant material according to claim 2, wherein a boron concentration is at least 5×10¹⁸ atoms/cm³ and no greater than 5×10¹⁹ atoms/cm³

4. The dopant material according to claim 3, further comprising oxygen, wherein an oxygen concentration that is measured by secondary ionization mass spectrometry is at least 1×10¹⁶ atoms/cm³ and no greater than 1×10¹⁸ atoms/cm³.

5. The dopant material according to claim 4, further comprising a first region positioned upstream in a first direction and a second region positioned downstream with respect to the first region in the first direction,
wherein the boron concentration in the first region is greater than the boron concentration in the second region, and the oxygen concentration in the first region is smaller than the oxygen concentration in the second region.

6. The dopant material according to claim 5, wherein the oxygen concentration decreases in a gradual or step-like manner moving from the second region toward the first region along the first direction.

7. The dopant material according to claim 6, wherein a reduction rate of the oxygen concentration in the first region is smaller than a reduction rate of the oxygen concentration in the second region.

8. A semiconductor substrate, comprising a semiconductor material to which the dopant material according to claim 1 is added.

9. A solar cell element comprising:
the semiconductor substrate according to the claim 8, wherein the semiconductor substrate comprises a first surface and a second surface corresponding to a rear surface of the first surface;
a first electrode that is positioned on the first surface of the semiconductor substrate; and
a second electrode that is positioned on the second surface of the semiconductor substrate.

10. A solar cell element comprising:
the semiconductor substrate according to the claim 8, that wherein the semiconductor substrate comprises a first surface and a second surface corresponding to a rear surface of the first surface; and
a first electrode and a second electrode that are positioned on the second surface of the semiconductor substrate and that output to the outside mutually different electrical charges.

11. The method for producing a dopant material according to claim 1 comprising:
generating a fused mixture by mixing and fusing a silicon material with an element that serves as the dopant source; and
generating a coagulate of the dopant material that comprises the element that serves as the dopant source and polycrystalline silicon by cooling and coagulating the fused mixture.

12. The method for producing the dopant material according to claim 11, further comprising coagulating the fused mixture successively toward one direction by cooling.

13. The method for producing the dopant material according to claim 12 further comprising for cutting the coagulate along a direction that is perpendicular to the one direction, and pulverizing the coagulate after cutting.

14. The method for producing the dopant material according to claim 11, wherein boron is used as the element that serves as the dopant source in generating the fused mixture.
